(19) United States
(12) Patent Application Publication
(10) Pub. No.: US 2005/0265075 A1
(43) Pub. Date: Dec. 1, 2005

(54) Recording method with processing units and apparatus using the same

(76) Inventors: Jen-Yi Huang, Hsinchu (TW); Chih-Wei Teng, Hsinchu (TW); Chen-Hung Chen, Hsinchu (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 11/129,832

(22) Filed: May 16, 2005

(30) Foreign Application Priority Data
May 21, 2004 (TW) 093114523

(51) Int. Cl. G11C 16/04

(52) U.S. Cl. 365/185.11

(57) ABSTRACT

The present invention relates to a method and an apparatus for recording data. The present invention provides a data recording method by using a reader processing unit, a writer processing unit, and selectively with at least one filter processing units to perform a recording operation. The method comprises steps by using the reader processing unit to read out data via a reading device, sending the readout data from the reader processing unit or the processed data from the filter processing unit to the writer processing unit, and using the writer processing unit to record data via a recording device.

### BACKGROUND OF THE INVENTION

1. Field of the Invention

The present invention relates to a method and an apparatus for transfer data among storage devices, and more particularly to a method and an apparatus for recording data by utilizing processing units.

2. Description of the Prior Art

In the recent years, due to the increasing demanding for storage media with larger capacities in different kinds of applications, various kinds of mass storage media have been developed. For example, optical discs are usually chosen for data backup and video playback for their long life time and exchangeability. However, especially in some real-time applications, the original data might have to be saved or processed by storage media with faster data transfer rate or capability of random access such as flash memory or hard disk drives. Therefore, there is a need to transfer data between different types of storage media with different data formats.

With reference to FIG. 1, the drawing shows an apparatus for transferring data between different storage devices of the prior art. The apparatus can be used to transfer data from a source medium 4a to a destination medium 5a. The data transfer is mainly performed by a host computer 2a connected with a reading device 1a and a recording device 3a with executing a data recording software 2b. The host computer 2a reads the data from the source medium 4a via the reading device 1a, and stores the data to the destination medium 5a via the recording device 3a. For example, the host computer 2a is a desktop computer, the reading device 1a is a hard disk drive, the source medium 4a is a hard disk of the hard disk drive, the recording device 3a is an optical storage device, and the destination medium 5a is a recordable optical disc. The desktop computer can execute the recording software 2b to transfer the data from the hard disk to the recordable optical disc.

Besides, as the recording speed of an optical storage device is increased, it is most important for the optical storage device to keep the recording operation in place and avoid “buffer under run” (or BURN) phenomenon. Even if the optical storage devices are configured with BURN proof technology, the recording may still fail due to inefficient data processing of the recording software. Even worse, that leads to write failure and waste of optical disk.

Accordingly, there is need to development for an optical disk device that can read and write data on the optical disk in more flexible way.

### SUMMARY OF THE INVNETION

It is an object of the present invention to provide a data recording method by using a reader processing unit, a writer processing unit, and selectively with at least one filter processing unit to perform a recording operation. The method includes steps by using the reader processing unit to read out data via a reading device, sending the readout data from the reader processing unit or the processed data from the filter processing unit to the writer processing unit, and using the writer processing unit to record data via a recording device.

In one embodiment, the writer processing unit further includes a writer buffer for data to be input from other processing unit when there is sufficient space in the writer buffer. The preceding processing unit of the writer processing unit further includes a threshold value such that if the available space of the writer buffer is larger than the threshold value, then the writer buffer is with sufficient space. Besides, at least one filter processing unit could have a filter buffer for its preceding processing unit to output its processed data. Similarly, the preceding processing unit could further have a threshold value such that if the available space of the filter buffer is larger than the threshold value, then the filter buffer is with sufficient space.

It is yet another object of the present invention to provide a data recording apparatus which includes a reading device for reading data from a source medium, a recording device for recording data to a destination medium, a reader processing unit for reading out data via the reading device, a writer processing unit for recording data via the recording device, and at least one filter processing unit arranged according to the flow of data processing for processing data from the reader processing unit or the preceding processing unit of the filter processing unit, and outputting processed data to the next processing unit of the filter processing unit or the recorder processing unit. The processing units altogether perform the recording operation in parallel.

It is yet another object of the present invention to provide a data recording apparatus which includes a reading device for reading data from a source medium, a recording device for recording data to a destination medium, a reader processing unit for reading out data via the reading device, and a writer processing unit for recording data via the recording device. The writer processing unit further includes a writer buffer for data to be input from the reader processing unit when there is sufficient space in the writer buffer. And in one embodiment, the reader processing unit further includes a threshold value such that if the available space of the writer buffer is larger than the threshold value, then the writer buffer is with sufficient space.

The processing units are implemented by hard-wired logic circuits or software executed by a microprocessor. And the reading device is an optical storage device, a flash memory reader, a floppy disk drive, or a hard disk drive; and the writing device is an optical storage device, a flash memory reader, a floppy disk drive, or a hard disk drive.

### BRIEF DESCRIPTIONN OF THE DRAWINGS

The present invention can be fully understood from the following detailed description and preferred embodiment with reference to the accompanying drawings in which:

FIG. 1 is a block diagram illustrating the structure of an apparatus for transferring data between different storage devices of the prior art;

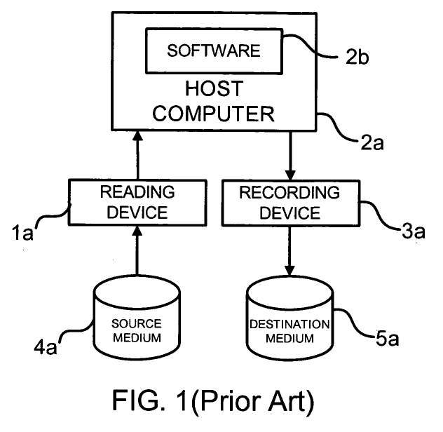

FIG. 2 is a block diagram illustrating the structure of an apparatus for transferring data between different storage devices according to one embodiment of the present invention;

FIG. 3 is a flowchart illustrating a recording method according to one embodiment of the present invention;

FIG. 4 is a block diagram illustrating the structure of an apparatus for transferring data between different storage devices according to another embodiment of the present invention; and

FIG. 5 is a flowchart illustrating a recording method according to another embodiment of the present invention.

### DETAILED DESCRIPTION OF THE PREFERRED EMBODIMENTS

The following detailed description is of the best presently contemplated modes of carrying out the invention. This description is not to be taken in a limiting sense, but is made merely for the purpose of illustrating general principles of embodiments of the invention. The scope of the invention is best defined by the appended claims.

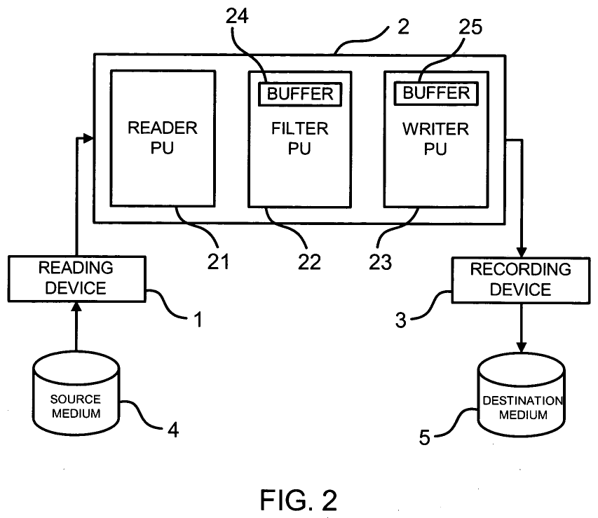

Referring to FIG. 2, it is a block diagram illustrating the structure of an apparatus for transferring data between different storage devices according to one embodiment of the present invention. The recording apparatus includes a reading device 1, a processing module 2, and a recording device 3. The reading device 1 that is used to access the data stored in a source medium 4 can be an optical storage device, a flash memory reader, a floppy disk drive, or a hard disk drive. The recording device 3 that is used to record data to a destination medium 5 can also be an optical storage device, a flash memory reader, a floppy disk drive, or a hard disk drive. As shown in FIG. 2, the processing module 2 includes three processing units (hereinafter as PUs): a reader PU 21, a filter PU 22, and a writer PU 23. Therefore it allows the data can be processed in a stage-by-stage sense. The reader PU 21 and a writer PU 23 are responsible for controlling the reading device 1 and the recording device 3, and are used to read and record data from the reading device 1 and to the recording device 3, respectively. The filter PU 22 is used as a bridge between the reader PU 21 and the writer PU 23. If the data format of the source medium 4 is not the same as that of the recording mode or the destination medium 5, then format of the data will adjusted by the filter PU 22.

People who skilled in this art can design different reader PU 21 for different types of reading device 1. Besides, the filter PU 22 further includes a filter buffer 24. When the filter buffer 24 has enough space, the output data from the reader PU 21 can be transferred to the filter buffer 24 as an input data for the filter PU 22. The filter PU 22 then processed the input data in the filter buffer 24 to adjust the data to fit the recording mode or the data format of the destination medium 5. Moreover, the writer PU 25 can also have different designs for different types of recording devices 3. The writer PU 25 further includes a writer buffer 25. When the writer buffer 25 has enough space, the output data from the filter PU 22 can be transferred to the writer buffer 25 as an input data for the writer PU 23. The writer PU 23 then transfers the data to the recording device 3 for recording data to the destination medium 5. The reader PU 21 and the filter PU 22 may each further have a threshold value such that if the available space of the buffer of the next PU is larger than the threshold value, then the buffer of the next PU is believed to be with sufficient space. For different data format and recording modes, different filter PU 22 can be designed and flexibly combined with different types of reader PU 21 and writer PU 23 for various kinds of data transferring applications.

In accordance with the embodiment, the source medium is a hard disk, the reading device is a hard disk drive, the write device is an optical storage device, and the destination medium is a CD-R disc. In this embodiment, the data stored in the hard disk with FAT format is going to be transferred to the CD-R disc with DAO (disc-at-once) recording mode. First the reader PU 21 reads out the data from the hard disk, and transfers the readout data to the filter buffer 24 when the filter buffer 24 has enough space. Since the data is recorded in units each with 2448 bytes (2352 main channel data and 96 sub channel data) in DAO recording mode, the filter PU 22 processes the data in the filter buffer 24 to data compliance with the DAO recording mode and transfers the processed data to the writer buffer 25 when there is enough space. The writer PU 23 will transfer these data in writer buffer 25 to the recording device to record the data to the destination medium.

More specifically speaking, the reading device 1 that is used to access the data stored in a source medium 4 can be an optical storage device, a flash memory reader, a floppy disk drive, or a hard disk drive. The recording device 3 that is used to record data to a destination medium 5 can also be an optical storage device, a flash memory reader, a floppy disk drive, or a hard disk drive.

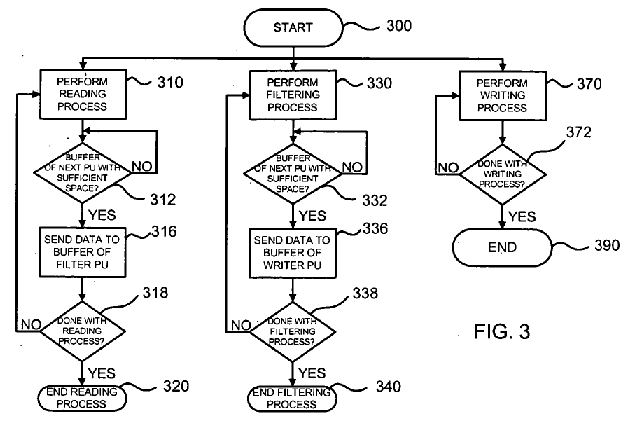

Referring to FIGS. 2 and 3, FIG. 3 is a flowchart illustrating a recording method according to one embodiment of the present invention. The present invention further provides a recording method according to one embodiment of the present invention that the data stored in the hard disk with FAT format and will be transferred to the CD-R disc with DAO (disc-at-once) recording mode. Before starting the process, arranging the processing module 2 with appropriate processing units. Then the reader PU 21, filter PU 22, and the writer PU 23 of the processing module 2 will perform the data transfer in parallel.

On one hand, in step 310, the reader PU 21 starts performing a reading process to read out the data from the source medium 4 via the reading device 1. And in step 312, determine if the filter buffer 24 of the filter PU 22 is with sufficient space. If there is no sufficient space in the filter buffer 24, then the process wait for enough space in the filter buffer 24. If there is sufficient space in the filter buffer 24, then the readout data is transferred to the filter buffer 24 for further processing as shown in step 316. After transferring the readout data to the buffer of the next PU, in step 318, the process checked if the whole reading process is completed. If the whole reading process is still on going, then the process returns to step 310 and reads more data from the source medium 4. If there are no further data needed to be read from the source medium 4, then the process moves to 320 and ends the reading process.

On another hand, in step 330, the filter PU 22 starts performing a filtering process for processing the data stored in the filter buffer 24. In this embodiment, the filter process converts the data in the filter buffer 24 into data conform to the DAO recording mode. And in step 332, determine if the writer buffer 25 of the writer PU 23 is with sufficient space. If there is no sufficient space in the writer buffer 25, then the process wait for enough space in the writer buffer 25. If there is sufficient space in the writer buffer 25, then the processed data is transferred to the writer buffer 25 for further processing as shown in step 336. After transferring the processed data to the buffer of the next PU, in step 338, the process checked if the whole filtering process is completed. If the whole filtering process is still on going, then the process returns to step 330 and keep on converting data stored in the filter buffer 24. If there are no further data needed to be processed by the filter PU 22, then the process moves to 340 and ends the filtering process.

On the other hand, in step 370, the writer PU 23 starts performing a writing process for recording the data stored in the writer buffer 25. In this embodiment, the writer PU 23 transfers the data that is ready for DAO recording and moved to the writer buffer 24 to the recording device 3 for further recording the data to the destination medium 5. And in step 372, the process checked if the whole writing process is completed. If the whole writing process is still on going, then the process returns to step 370 and keep on recording data to the destination medium 5 via the recording device 3. If there are no further data needed to be recorded by the writer PU 23, then the process moves to 390 and ends the process of the whole processing module 2.

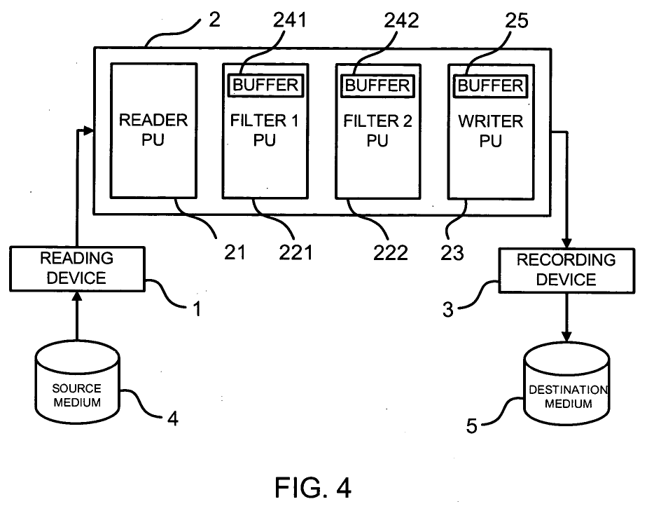

Referring to FIG. 4, it is a block diagram illustrating the structure of an apparatus for transferring data between different storage devices according to another embodiment of the present invention. The recording apparatus includes a reading device 1, a processing module 2, and a recording device 3 as mentioned in the previous embodiment. As abovementioned embodiment, the reading device 1 can be an optical storage device, a flash memory reader, a floppy disk drive, or a hard disk drive. The recording device 3 can also be an optical storage device, a flash memory reader, a floppy disk drive, or a hard disk drive. Comparing FIG. 4 with FIG. 2, addition to the reader PU 21 and the writer PU 23, the processing module 2 further includes a first filter PU 221 and a second filter PU 222. Similarly, it also allows the data can be processed in a stage-by-stage sense. The actions of reader PU 21 and a writer PU 23 are similar to the previous embodiment and not further explained here. The first filter PU 221 and the second filter PU 222 are together used as the bridge between the reader PU 21 and the writer PU 23. If the data format of the source medium 4 is not the same as that of the writing mode or the destination medium 5, then format of the data will adjusted by the first filter PU 221 and the second filter PU 222.

The first filter PU 221 further includes a first filter buffer 241. When the first filter buffer 241 has enough space, the output data from the reader PU 21 can be transferred to the first filter buffer 241 as an input data for the first filter PU 221. The first filter PU 221 then processed the input data in the first filter buffer 241. Besides, the second filter PU 222 also includes a second filter buffer 242. When the second filter buffer 242 has enough space, the output data from the first filter PU 221 can be transferred to the second filter buffer 242 as an input data for the second filter PU 222. The second filter PU 222 then processed the input data in the second filter buffer 242. Thus the data can then be adjusted to fit the recording mode or the data format of the destination medium 5. Then when the writer buffer 25 has enough space, the output data from the second filter PU 222 can be transferred to the writer buffer 25 as an input data for the writer PU 23. The writer PU 23 then transfers the data to the recording device 3 for recording data to the destination medium 5.

In accordance with the embodiment, the source medium is a hard disk, the reading device is a hard disk drive, the write device is an optical storage device, and the destination medium is a CD-R disc. In this embodiment, the data stored in the hard disk with MP3 format is going to be transferred to the CD-R disc as CD-Audio format data with DAO (disc-at-once) recording mode. First the reader PU 21 reads out the data from the hard disk, and transfers the readout data to the first filter buffer 241 when the first filter buffer 241 has enough space. The first filter PU will process the data in the first filter buffer 241 to make the data from the MP3 format to the CD-Audio format. And the first filter PU 221 transfers the processed data to the second filter buffer 242 when the second filter buffer 242 has enough space. Because the data is recorded in units each with 2448 bytes (2352 main channel data and 96 sub channel data) in DAO recording mode, the second filter PU 222 processes the CD-Audio data in the second filter buffer 242 to data compliance with the DAO recording mode and transfers the processed data to the writer buffer 25 when there is enough space. The writer PU 23 will transfer these data in writer buffer 25 to the recording device to record the data to the destination medium.

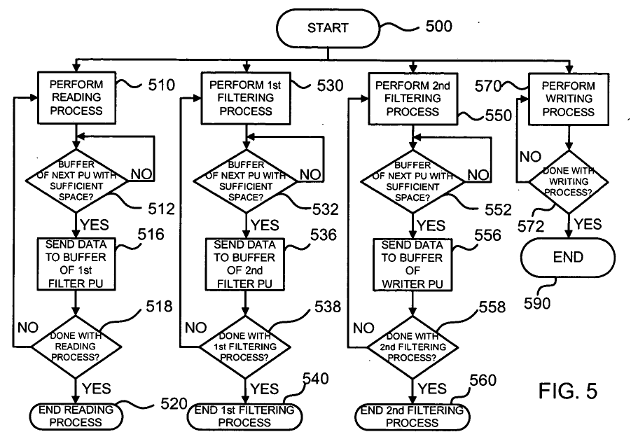

Referring to FIGS. 4 and 5, FIG. 5 is a flowchart illustrating a recording method according to another embodiment of the present invention. The embodiment of the present invention shows that the data stored in the hard disk with MP3 format and will be converted to CD-Audio format and transferred to the CD-R disc with DAO (disc-at-once) recording mode. Before starting the process, preparing the processing module 2 with appropriate processing units. Then the reader PU 21, first filter PU 221, second filter PU 222, and the writer PU 23 of the processing module 2 will altogether perform the recording operation in parallel.

On one hand, in step 510, the reader PU 21 starts performing a reading process to read out the data from the source medium 4 via the reading device 1. And in step 512, determine if the first filter buffer 241 of the first filter PU 221 is with sufficient space. If there is no sufficient space in the first filter buffer 241, then the process wait for enough space in the first filter buffer 241. If there is sufficient space in the first filter buffer 241, then the readout data is transferred to the first filter buffer 241 for further processing as shown in step 516. After transferring the readout data to the buffer of the next PU, in step 518, the process checked if the whole reading process is completed. If the whole reading process is still on going, then the process returns to step 510 and reads more data from the source medium 4. If there are no further data needed to be read from the source medium 4, then the process moves to 520 and ends the reading process.

On another hand, in step 530, the first filter PU 221 starts performing a first filtering process for processing the data stored in the first filter buffer 241. In this embodiment, the first filter process converts the data in the first filter buffer 241 into data conform to the CD-Audio format. And in step 532, determine if the second filter buffer 242 of the second filter PU 222 is with sufficient space. If there is no sufficient space in the second filter buffer 242, then the process wait for enough space in the second filter buffer 242. If there is sufficient space in the second filter buffer 242, then the processed data is transferred to the second filter buffer 242 for further processing as shown in step 536. After transferring the processed data to the buffer of the next PU, in step 538, the process checked if the first filtering process is completed. If the first filtering process is still on going, then the process returns to step 530 and keep on converting data stored in the first filter buffer 241. If there are no further data needed to be processed by the first filter PU 221, then the process moves to 540 and ends the first filtering process.

On another hand, in step 550, the second filter PU 221 starts performing a second filtering process for processing the data stored in the second filter buffer 242. In this embodiment, the second filter process converts the CD-Audio format data in the second filter buffer 242 into data conform to the DAO recording mode. And in step 552, determine if the writer buffer 25 of the writer PU 23 is with sufficient space. If there is no sufficient space in the writer buffer 25, then the process wait for enough space in the writer buffer 25. If there is sufficient space in the writer buffer 25, then the processed data is transferred to the writer buffer 25 for further processing as shown in step 556. After transferring the processed data to the buffer of the next PU, in step 558, the process checked if the second filtering process is completed. If the second filtering process is still on going, then the process returns to step 550 and keep on converting data stored in the second filter buffer 242. If there are no further data needed to be processed by the second filter PU 221, then the process moves to 560 and ends the second filtering process.

On the other hand, in step 570, the writer PU 23 starts performing a writing process for recording the data stored in the writer buffer 25. In this embodiment, the writer PU 23 transfers the data that is ready for DAO recording and stored in the writer buffer 24 to the recording device 3 for the recording device 3 further recording the data to the destination medium 5. And in step 572, the process checked if the whole writing process is completed. If the whole writing process is still on going, then the process returns to step 570 and keep on recording data to the destination medium 5 via the recording device 3. If there are no further data needed to be recorded by the writer PU 23, then the process moves to 590 and ends the process of the whole processing module 2.

People who skilled in this art can design different processing units for different applications. And the total number of processing units can be altered for different requests for recording operations. For example, there could be no filter PU for performing a simple doubling operation, one filter PU for performing recording operation with simple data conversion, or more than two filter PUs for performing complicated data recording operations including encryption, decryption, and encoding. Generally speaking, a processing module can include a reader PU, a writer PU, and M units of filter PUs, where M is a non-negative integer. Usually the reader PU would be the first PU that reads out the data, and the writer PU would be the last PU that records data. Other filter PUs are arranged according to the flow of data processing. If M equals 0, which means that the readout data from the reader PU is sent to the writer PU for recording directly. If M equals 1, then the readout data from reader PU would be processed by the filter PU, then sent to the writer PU for recording. If M is greater than 1, then the readout data from reader PU would be processed by the first filter PU. After that, each Nth filter PU would output its processed data to the (N+1)th filter PU, wherein N is a positive integer. And finally the processed data of Mth filter PU would be sent to the writer PU for recording. Each processing unit may have a buffer for the preceding processing unit to output its processed data. And each processing unit may further have a threshold value such that if the available space of the buffer of the next processing unit is larger than the threshold value, then the buffer of the next processing unit is believed to be with sufficient space. Moreover, the aforementioned processing units can be implemented by hard-wired logic circuits or software executed by a microprocessor.

While the invention has been described with reference to the preferred embodiments, the description is not intended to be construed in a limiting sense. It is therefore contemplated that the appended claims will cover any such modifications or embodiments as may fall within the scope of the invention defined by the following claims and their equivalents.

1. A data recording method by using a reader processing unit, a writer processing unit, and M filter processing units to perform a recording operation, where M is a non-negative integer, the method comprising steps of:
using the reader processing unit to read out data via a reading device;
if M=0, sending the readout data from the reader processing unit to the writer processing unit;
if M=1, processing the readout data by the filter processing unit, and sending the processed data from the filter processing unit to the writer processing unit; if M>1, processing the readout data by the first filter processing unit, and each Nth filter processing unit outputting its processed data to the (N+1)th filter processing unit, wherein N is an positive integer, and sending the processed data from the Mth filter processing unit to the writer processing unit; and
using the writer processing unit to record data via a recording device.

2. The data recording method according to claim 1, wherein the writer processing unit further comprising a writer buffer for data to be input from other processing unit when there is sufficient space in the writer buffer.

3. The data recording method according to claim 2, wherein the preceding processing unit of the writer processing unit further comprising a threshold value such that if the available space of the writer buffer is larger than the threshold value, then the writer buffer is with sufficient space.

4. The data recording method according to claim 1, wherein the at lease one filter processing unit comprises a filter buffer for its preceding processing unit to output its processed data.

5. The data recording method according to claim 4, wherein the preceding processing unit of the filter processing unit further comprises a threshold value such that if the available space of the filter buffer is larger than the threshold value, then the filter buffer is with sufficient space.

6. The data recording method according to claim 1, wherein the processing units altogether perform the recording operation in parallel.

7. The data recording method according to claim 1, wherein the processing units are implemented by hard-wired logic circuits or software executed by a microprocessor.

8. The data recording method according to claim 1, wherein the reading device is an optical storage device, a flash memory reader, a floppy disk drive, or a hard disk drive.

9. The data recording method according to claim 1, wherein the recording device is an optical storage device, a flash memory reader, a floppy disk drive, or a hard disk drive.

10. A data recording apparatus, comprising:
a reading device for reading data from a source medium;
a recording device for recording data to a destination medium;
a reader processing unit for reading out data via the reading device;
a writer processing unit for recording data via the recording device; and
at least one filter processing unit arranged according to the flow of data processing for processing data from the reader processing unit or the preceding processing unit of the filter processing unit, and outputting processed data to the next processing unit of the filter processing unit or the recorder processing unit.

11. The data recording apparatus according to claim 10, wherein the writer processing unit further comprising a writer buffer for data to be input from other processing unit when there is sufficient space in the writer buffer.

12. The data recording apparatus according to claim 11, wherein the preceding processing unit of the writer processing unit further comprising a threshold value such that if the available space of the writer buffer is larger than the threshold value, then the writer buffer is with sufficient space.

13. The data recording apparatus according to claim 10, wherein at least one filter processing unit comprises a filter buffer for the preceding processing unit to output its processed data.

14. The data recording apparatus according to claim 13, wherein the preceding processing unit of the filter processing unit further comprises a threshold value such that if the available space of the filter buffer is larger than the threshold value, then the filter buffer is with sufficient space.

15. The data recording apparatus according to claim 10, wherein the processing units are implemented by hard-wired logic circuits or software executed by a microprocessor.

16. The data recording apparatus according to claim 10, wherein the reading device is an optical storage device, a flash memory reader, a floppy disk drive, or a hard disk drive; and the writing device is an optical storage device, a flash memory reader, a floppy disk drive, or a hard disk drive.

17. A data recording apparatus, comprising:
a reading device for reading data from a source medium;
a recording device for recording data to a destination medium;
a reader processing unit for reading out data via the reading device; and
a writer processing unit for recording data via the recording device;
wherein the writer processing unit further comprising a writer buffer for data to be input from the reader processing unit when there is sufficient space in the writer buffer.

18. The data recording apparatus according to claim 17, wherein the reader processing unit further comprises a threshold value such that if the available space of the writer buffer is larger than the threshold value, then the writer buffer is with sufficient space.

19. The data recording apparatus according to claim 17, wherein the processing units are implemented by hard-wired logic circuits or software executed by a microprocessor.

20. The data recording apparatus according to claim 17, wherein the reading device is an optical storage device, a flash memory reader, a floppy disk drive, or a hard disk drive; and the writing device is an optical storage device, a flash memory reader, a floppy disk drive, or a hard disk drive.
